(19) United States
(12) Patent Application Publication
(10) Pub. No.: US 2026/0025931 A1
(43) Pub. Date: Jan. 22, 2026

(54) METHOD FOR MOUNTING AN ELECTRONIC COMPONENT IN A PRINTED CIRCUIT BOARD, METHOD FOR PRODUCING A MULTILAYER PRINTED CIRCUIT BOARD AND PRINTED CIRCUIT BOARD OBTAINED BY THIS METHOD

(71) Applicant: SAFRAN ELECTRONICS & DEFENSE, PARIS (FR)

(72) Inventors: Bruno LEFEVRE, MOISSY CRAMAYEL (FR); Patrice CHETANNEAU, MOISSY CRAMAYEL (FR)

(21) Appl. No.: 18/997,603

(22) PCT Filed: Jul. 12, 2023
(86) PCT No.: PCT/FR2023/051084

§ 371 Date: Jan. 22, 2025

(30) Foreign Application Priority Data
Jul. 26, 2022 (FR) FR2207676

(51) Int. Cl. H05K 3/34; H05K 1/02; H05K 1/18

(52) U.S. Cl. CPC H05K 3/341; H05K 1/0298; H05K 1/181; H05K 1/185; H05K 3/3485

(57) ABSTRACT

A method for mounting an electronic component to a conductive layer of a printed circuit board, the method including 1) depositing a solder paste on the conductive layer, the solder paste including tin, copper balls and a solder flux; 2) positioning the electronic component on the solder paste; then 3) diffusion-soldering the electronic component. Another aspect relates to a method for producing a multilayer printed circuit board, the method including a) mounting at least a first electronic component on an inner conductive layer of a printed circuit board; b) depositing a dielectric layer on the first electronic component and the inner conductive layer; and c) mounting at least a second electronic component on an outer conductive layer of the printed circuit board.

### TECHNICAL FIELD OF THE INVENTION

The present invention relates to a method for assembling an electronic component in a printed circuit board wherein the electronic component is connected to the printed circuit board by diffusion soldering. It also relates to a method for manufacturing a multilayer printed circuit board avoiding problems associated with reflows of the soldering material. The invention also relates to a printed circuit board including buried components obtained by this method.

The invention finds applications in the field of manufacture of electronic boards and, in particular, in the field of manufacture of electronic boards intended for aeronautics.

### TECHNOLOGICAL BACKGROUND OF THE INVENTION

In aeronautics, many functions are carried out by means of thermal or hydraulic devices. However, the desire to reduce greenhouse gas emissions has led to these thermal and hydraulic functions being replaced with electrical or electronic functions. Power electronics applied to aeronautics has therefore been on the rise in recent years. The power electronics available on the market is not, however, totally adapted to aeronautics. Indeed, for use in aeronautics, electronic boards need to be more efficient as well as of lower mass or overall size. For this, aeronautic manufacturers are seeking to increase functions and power available within an electronic board, also referred to as a printed circuit board, by integrating a maximum number of components within a same printed circuit board. Indeed, as represented in FIG. 1, a conventional printed circuit board 10 comprises electronic components 14 connected to one external face 12 (or outer conductive layer) of the printed circuit board or to both external faces 12 of the printed circuit board, each outer conductive layer 12 resting on a dielectric layer 11. Techniques have been implemented to also integrate electronic components, referred to as buried components, inside the printed circuit board. Such buried components then have be connected to an inner conductive layer, housed between two dielectric layers.

One way of integrating components into printed circuit boards is to bury the components in substrates of printed circuit boards such as, for example, organic type PCBs (Printed Circuit Boards), in order to form highly integrated SIP (System in Package) type digital modules or power modules. However, burial of components in the substrates of printed circuit boards has limitations caused by the assembly of said components on the metal tracks, also referred to as metal layers or conductive layers, of the printed circuit board. Indeed, each of the methods currently used for burying components within a printed circuit board has drawbacks related to the assembly of the components to the inner metal layer, generally of copper, of the printed circuit board.

The most commonly used method today resorts to manufacturing copper-filled laser vias. This method requires the use of copper-terminated components and chips. However, the variety of this type of compound is still quite small, and these compounds are only available for very large production volumes.

An alternative method, still under study, for connecting components buried in a printed circuit board consists in conductive bonding with silver-finish components. This method is still poorly documented and does not seem to provide sufficient reliability for highly stressed aeronautical devices, especially in terms of vibration.

Another method consists in connecting the components buried in the printed circuit board by a soldering method identical to that used to connect the components to the external faces of the printed circuit board. This method makes it possible to use standard components which are easy to find on the market and to connect them using a known soldering technique. These standard components, referred to as COTS (Commercial Off-The-Shelf), are assembled to the inner metal circuit by conventional soft soldering, at a melting temperature close to 220° C., using a known tin-based soldering material. In the form most commonly used in electronics today, the soldering material, also referred to as solder bead, is formed from an alloy of tin, silver and copper (Sn96.5Ag3.0Cu0.5) and is known as ‘SAC305’. However, this method leads to reflow of the solder bead of the component buried in the circuit when the surface components are soldered with the same type of alloy, which leads to the risk of short-circuit inside the printed circuit board. Indeed, this method consists in assembling the buried components to an inner metal layer of the printed circuit board through soldering by means of a SAC305 solder bead. This first soldering involves heating the buried components and the inner metal layer to the melting temperature of the solder bead, generally a temperature in the order of 245° C. or 260° C. depending on the type of component to be soldered. Above a dielectric layer covering the buried components and the inner metal layer, an outer metal layer to which outer electronic components are assembled, extends. These outer electronic components are connected by the same soldering method as the buried components. This soldering of the outer components involves heating said outer components and the outer metal layer to the same temperature as for the first soldering. Since the layers are stacked, the second soldering also involves heating the buried components and the inner metal layer again to this same melting temperature of the solder bead. There is therefore a reflow of the soldering material in the inner layer. This reflow of the inner soldering material, combined with the possibility of delamination within the printed circuit board, can cause short circuits. Indeed, due to reflow, the soldering material becomes liquid again and can extend into the spaces between the metal layer and the dielectric layer until it creates an unwanted connection with the metal layer and/or another inner electronic component.

To avoid this reflow, it has been contemplated to use soldering materials based on alloys with higher melting points than SAC305 for the connection of buried components. However, most electronic boxes are not designed or approved for this type of assembly. Indeed, the electronic components used have to be qualified to withstand these higher temperatures. Yet, the components found on the market, such as so-called ‘lead free compliant’ components, referred to as RoHS, are qualified for assembling methods at 245° C. or 260° C. (according to JEDEC standards) and are therefore not compatible with high-temperature soldering.

There is therefore a real need for a new method for assembling buried components, avoiding reflow of the soldering material with all the ensuing consequences.

### SUMMARY OF THE INVENTION

To address the problems discussed above of reflow of the soldering material used when assembling buried electronic components, the applicant provides a method for assembling a buried component using a solder paste essentially containing copper and tin and allowing diffusion soldering. The applicant also provides a method for manufacturing a multilayer printed circuit board (PCB) wherein the buried component(s) are connected by diffusion soldering using this solder paste.

“Soldering” refers to a permanent assembling method establishing a metal bond between two metal parts, without melting the edges of the metal parts and, in particular, between an electronic component and a metal track of a printed circuit board. In the invention, the soldering considered is soldering with the addition of a metal-based soldering material, wherein the soldering material is brought to its melting temperature (lower than that of the metals to be assembled) to become liquid and thus wet, by capillary action, the parts to be assembled.

According to a first aspect, the invention relates to a method for assembling an electronic component to a conductive layer of a printed circuit board, including the following operations of:
depositing a solder paste onto the conductive layer, said solder paste including tin, copper balls and a soldering flux,
positioning the electronic component on the solder paste, and then
soldering by diffusion said electronic component.

This method makes it possible to connect an inner electronic component to
a printed circuit board without the risk of reflow of the soldering material when the components are assembled in outer layers.

A second aspect of the invention relates to a method for manufacturing a multilayer printed circuit board, including the following steps of:
a) assembling at least one first electronic component to an inner conductive layer of a printed circuit board,
b) depositing a dielectric layer onto the first electronic component and the inner conductive layer, and
c) assembling at least one second electronic component to an outer conductive layer of the printed circuit board, step a) of assembling the first electronic component being in accordance with the assembling method as defined above.

This method makes it possible to manufacture a multilayer printed circuit board with inner electronic components without the risk of short-circuits, in the inner layers, caused by the reflow of the soldering material. Indeed, the fact of using two distinct soldering materials, one of which includes a reflow temperature much higher than its initial melting temperature, makes it possible to create one or more inner layers without the risk of reflow of the soldering material used in these inner layers.

Further to the characteristics just discussed in the preceding paragraph, the manufacturing method according to one aspect of the invention may have one or more complementary characteristics from among the following, considered individually or according to all technically possible combinations:
step c) of assembling the second electronic component includes the operations of depositing a solder bead onto an outer conductive layer, positioning the second electronic component on the solder bead, and softly soldering the second electronic component.
the solder bead comprises a tin-based alloy, distinct from the solder paste used for the first component.
the solder paste comprises a melting temperature and a reflow temperature distinct from each other, the reflow temperature being substantially higher than the melting temperature, and the solder bead comprises a single melting temperature.
the reflow temperature of the solder paste is at least 100° C. higher than the melting temperature of said solder paste.
step a) of assembling the first electronic component and step c) of assembling the second electronic component each include an operation of heating the solder bead and the solder paste to a maximum temperature of 260° C.
it includes a plurality of steps a) of assembling the first electronic component and steps b) of depositing a dielectric layer, made successively one after the other before step c) of assembling the second electronic component, an inner layer of the multilayer printed circuit board being formed after each set of a step a) and a step b).

A third aspect of the invention relates to a multilayer printed circuit board comprising at least a first and a second electronic component connected to an inner and an outer conductive layer respectively, said inner and outer conductive layers being separated from each other by a dielectric layer, characterised in that it is obtained by the manufacturing method as defined above.

### BRIEF DESCRIPTION OF THE FIGURES

Further advantages and characteristics of the invention will become

apparent upon reading the following description, illustrated by the figures in which:

FIG. 1, already described, represents a schematic cross-section view of a conventional multilayer printed circuit board;

FIG. 2 represents two examples of solder paste used, according to the invention, for assembling the components buried in the inner conductive layer; and

FIG. 3 represents, according to schematic cross-sectional views, the different operations and steps of the method for manufacturing a printed circuit board according to the invention.

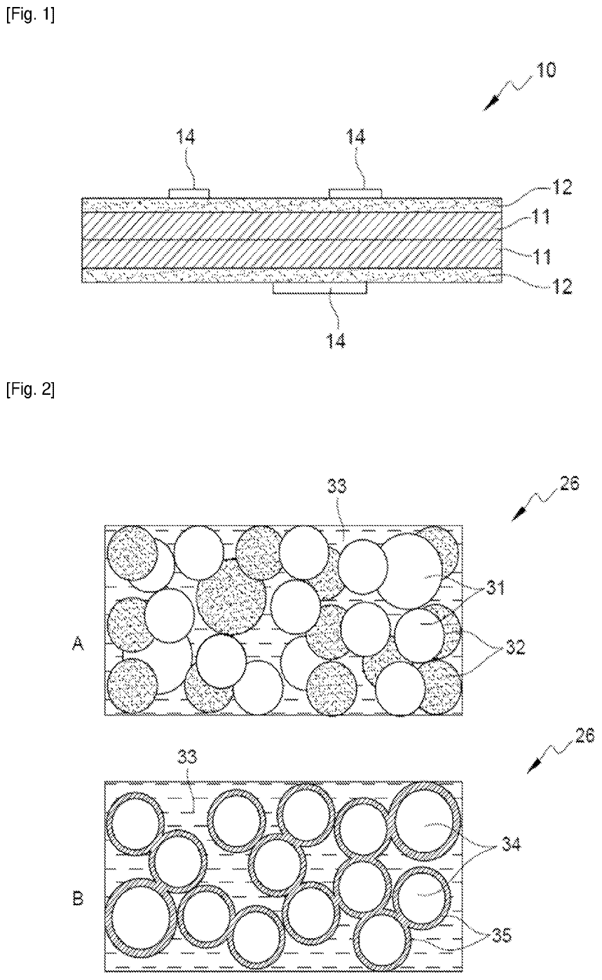

### DETAILED DESCRIPTION

An exemplary embodiment of a method for assembling a buried component and an exemplary embodiment of a method for manufacturing a multilayer printed circuit board incorporating this assembling method are described in detail hereinafter, with reference to the appended drawings. These examples illustrate the characteristics and advantages of the invention. It should be noted, however, that the invention is not limited to these examples.

In the figures, identical elements are marked by identical references. For reasons of legibility of the figures, the size scales between the elements represented are not respected.

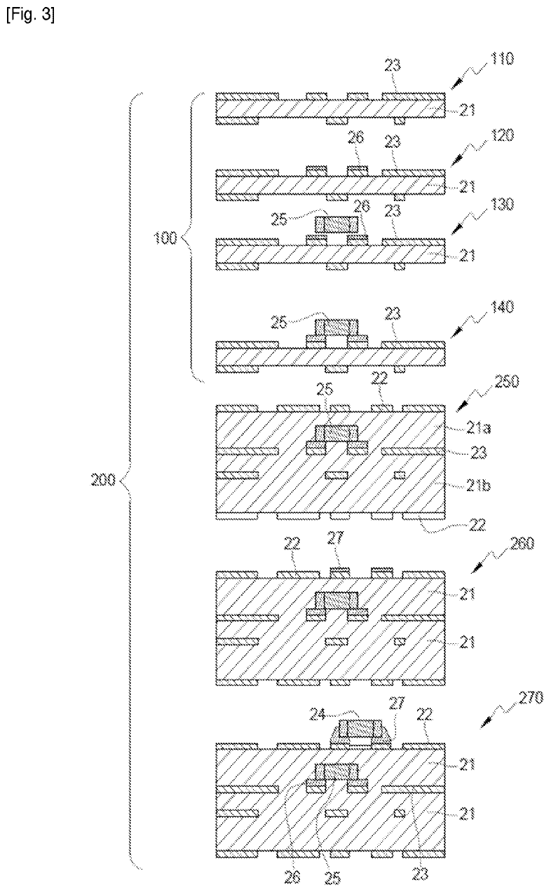

An example of a method 100 for assembling an inner electronic component, also referred to as the first electronic component or buried component, to a conductive layer of a printed circuit board, is represented in FIG. 3. This assembling method 100 includes an operation 110 of making the conductive layer 23 to which it is intended to connect the buried component 25. This conductive layer 23, also referred to as a metal track, is an etched track in an electrically conductive material such as copper, for example. This conductive layer 23, initially deposited onto a dielectric layer 21, is etched by photolithography or by any other etching technique known in the field of printed circuit boards.

The assembling method 100 then includes an operation 120 of depositing solder paste 26 at the location where the buried component 25 is to be positioned. An operation 130 then consists in positioning the buried component 25 above the solder paste 26. These operations 110 to 130 together constitute an operation known as positioning of the buried component.

The assembling method 100 then includes an operation 140 of soldering by diffusion the buried component 25. This soldering operation 140 consists in heating the solder paste 26 to a soldering temperature which makes it possible to render said solder paste fluid. The soldering temperature, referred to more simply as the melting temperature, is a temperature at least equal to the melting temperature of the solder paste. Heating the solder paste 26 can be carried out by installing the partially formed assembly of the printed circuit board-that is, the assembly including (at this stage of the method) the conductive layer 23 resting on the dielectric layer 21, the buried component 25 and the solder paste 26-into a heating device, such as a furnace, in which a heat substantially higher than the melting temperature of the solder paste prevails. Under the effect of the melting temperature and the time above the melting point, the solder paste 26 is transformed into inner soldered joints allowing electrical connection with the inner conductive layer.

The solder paste 26 according to the invention is a solder paste conventionally used in TLPS (Transient Liquid Phase Sintering) technology for soldering standard tin-finish Surface-Mounted Components (or SMCs) with a furnace profile close to that used with a conventional soldering material (of the SAC305 type described hereinafter). This solder paste 26 is a substance consisting of a mixture of tin (Sn) and copper (Cu) balls. In a first alternative, represented in drawing A of FIG. 2, the solder paste is in the form of copper balls 31 and tin balls 32 mixed in a soldering flux 33. In a second alternative, represented in drawing B of FIG. 2, the solder paste 26 is in the form of copper balls 34 covered with a thin layer of tin 35 and mixed with a flux 33. Whatever the alternative (drawing A or drawing B), the tin melts during soldering, that is, under the effect of the melting temperature, and a tin/copper inter-diffusion takes place to form a bronze (CuSn) whose melting point is much higher than 400° C. The melting temperature of the solder paste 26, that is, the temperature to which the partially formed assembly of the printed circuit board is brought during operation 140, is in the order of 250° C. After cooling, the buried component 25 is assembled with the conductive layer 23. The bronze formed by the tin/copper inter-diffusion has a melting point much higher than 400° C. and therefore well much higher than the melting temperature. This melting point of the bronze corresponds to a so-called “reflow” temperature, that is, the temperature at which the solder paste melts a second time.

As this reflow temperature is much higher than the melting temperature of the solder paste 26, there is no risk of reflow of said solder paste when soldering the outer electronic components 14, or surface components, as will be explained hereinafter.

This type of diffusion soldering using a solder paste such as that described above makes it possible to assemble tin-finish components at soldering temperatures similar to those used with the alloy referred to as ‘SAC305’, with the advantage that the solder paste no longer remelts during subsequent assemblies, which eliminates the risk of having short circuits when assembling surface-mounted components with the SAC305 alloy.

The method for manufacturing 200 a multilayer printed circuit board according to the invention is represented functionally in FIG. 3. This manufacturing method 200 includes all the operations of the assembling method 100 described previously. It further includes, after the soldering operation 140, a step 250 of depositing at least one dielectric layer 21 onto the buried component 25 and the inner conductive layer 23. In the example of FIG. 3, this step 250 includes depositing an upper dielectric layer 21a, deposited above the inner conductive layer 23, and depositing a lower dielectric layer 21b, deposited below said inner conductive layer 23. These dielectric layers 21 are layers formed from a dielectric material and deposited according to one of the techniques conventionally used in the field of printed circuit boards to form a dielectric layer. The dielectric layer 21, also referred to as prepreg, can be formed, for example, from a structuring fabric and a dielectric resin, the structuring fabric may especially be a glass fabric and the dielectric resin, an epoxy resin.

Step 250 also includes an operation of etching an outer conductive layer 22, or metal track, on the surface of the printed circuit board. This outer conductive layer 22 is made in the same way as the inner conductive layer 23.

The manufacturing method 200 then includes a step of assembling the second electronic component 24, or surface component, to the outer conductive layer 22. This step of assembling the surface component 24 comprises an operation 260 of depositing the solder bead 27 at the location where the surface component 24 is to be positioned. The surface component 24 is then positioned on the solder bead 27 before the implementation of the soft soldering operation 270 using a tin-based soldering material 27. This solder bead 27 is a conventional soldering material, as usually used in the field of printed circuit boards. This solder bead can, for example, be formed essentially from tin, such as SAC305 alloy.

The soldering operation 270 consists in heating the printed circuit board assembly to the soldering temperature adapted to the material of the soldering bead 27 to make said material fluid. The soldering temperature of operation 270 is a temperature at least equal to the melting temperature of the solder bead 27. Heating of the solder bead 27 can be carried out, as in step 140 of the assembling method 100, by installing the printed circuit board assembly (that is, all the layers comprising the components, the soldering materials, the conductive layers and the dielectric layers) in a heating device, such as a furnace, in which a heat substantially equal to the melting temperature of the solder bead 27 prevails. For a solder bead of the SAC305 type, the melting temperature of the soldering operation 270 is 260° C. maximum. Thus, the melting temperature of the soldering operation 270 of the surface component is approximately the same as the melting temperature of the soldering operation 140 of the buried component. The soldering operation 270 allows the solder bead 27 to melt and form outer soldered joints (connecting the surface component 24 to the outer conductive layer) without reflow of the inner soldered joints (connecting the buried component to the inner conductive layer)-that is, without the inner soldered joints becoming fluid again-because the melting point of said inner soldered joints has become higher (400° C.), after the first melting, than that of the solder bead 27.

The manufacturing method 200 is therefore implemented with a soldering temperature lower than 260° C.; it is therefore perfectly compatible with standard electronic components and standard printed circuit boards. It also provides the advantage of not causing reflow of the inner soldered joint, which allows components to be buried inside the printed circuit board by means of a simple soldering method, without the risk of generating short circuits.

The use of two distinct soldering materials, for the inner and outer components, can also allow better cleaning of printed circuit boards. Indeed, the advantage of the solder paste 26 is that it does not form a meniscus (unlike conventional tin solder) under the component, which creates a larger space under the component, allowing liquids to circulate freely during cleaning. The use of two distinct soldering materials, for the inner and outer components, can also improve the adhesion of the epoxy resin to the inner soldered joints during dielectric layer deposition operations. Indeed, as the joint does not melt, it is granular, allowing better adhesion of the resin.

The assembling method 100 and the manufacturing method 200 according to the invention have been described for a buried component 25 and a surface component 24. It will be understood by those skilled in the art that a plurality of buried components may be assembled in the same way as the buried component 25 and a plurality of surface components may be assembled in the same way as the surface component 24. Those skilled in the art will also understand that a plurality of inner layers, each comprising an inner conductive layer 23 and one or more inner components 25, may be buried inside the printed circuit board, each inner layer being separated from the next inner layer by a dielectric layer 21. Indeed, as the inner components of each inner layer are soldered by means of solder paste 26, there is no risk of reflow of the inner soldered joints whatever the number of soldering operations performed on the printed circuit board.

The assembling method 100 according to the invention thus makes it possible to generate inner layers with connection of components buried in printed circuit boards, such as organic electronic boards, SIP modules, power modules or PCB packaging, without the risk of reflow of the solders of the inner components during final assembly in a furnace.

Although described through a number of examples, alternatives and manufacturing methods, the method for assembling a buried component and the method for manufacturing a multilayer printed circuit board according to the invention comprise various alternatives, modifications and improvements which will be obvious to those skilled in the art, it being understood that these alternatives, modifications and improvements are within the scope of the invention.

1. A method for manufacturing a multilayer printed circuit board, comprising:
a) assembling at least one first electronic component to an inner conductive layer of a printed circuit board, said assembling including the following operations of:
1) depositing a solder paste onto the conductive layer, said solder paste including tin, copper balls and a soldering flux,
2) positioning the electronic component on the solder paste, and then
3) soldering by diffusion said electronic component.
b) depositing a dielectric layer onto the first electronic component and the inner conductive layer; and
c) assembling at least one second electronic component to an outer conductive layer of the printed circuit board, said assembling of the second electronic component including the following operations of:
i. depositing a solder bead onto an outer conductive layer,
ii. positioning the second electronic component on the solder bead, and
iii. softly soldering the second electronic component, characterised in that the solder bead comprises a tin-based alloy, distinct from the solder paste.

2. The method according to claim 1, wherein:
the solder paste comprises a melting temperature and a reflow temperature distinct from each other, the reflow temperature being substantially higher than the melting temperature, and
the solder bead comprises a single melting temperature.

3. The method according to claim 2, wherein the reflow temperature of the solder paste is at least 100° C. higher than the melting temperature of said solder paste.

4. The method according to claim 1, wherein the step a) of assembling the first electronic component and the step c) of assembling the second electronic component each include an operation of heating the solder bead and the solder paste to a maximum temperature of 260° C.

5. The method according to claim 1, comprising a plurality of steps a) of assembling the first electronic component and steps b) of depositing a dielectric layer, carried out successively one after the other before the step c) of assembling the second electronic component, an inner layer of the multilayer printed circuit board being formed after each set of a step a) and a step b).

6. A multilayer printed circuit board including at least a first and a second electronic component connected to an inner conductive layer and an outer conductive layer respectively, said inner and outer conductive layers being separated from each other by a dielectric layer,
the multilayer printed circuit board being obtained by the manufacturing method according to claim 1.
